(19) United States
(12) Patent Application Publication
(10) Pub. No.: US 2007/0114540 A1
(43) Pub. Date: May 24, 2007

(54) Nitride semiconductor light emitting device

(75) Inventors: Seong Suk Lee, Suwon (KR); Kyeong Ik Min, Seoul (KR); Soo Han Kim, Sungnam (KR); Min Ho Kim, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/600,870

(22) Filed: Nov. 17, 2006

(30) Foreign Application Priority Data
Nov. 19, 2005 (KR) 10-2005-0111057

(51) Int. Cl. H01L 33/00

(52) U.S. Cl. 257/79

(57) ABSTRACT

Disclosed herein is a nitride semiconductor light emitting device, which comprises plural active layers emitting light of different wavelengths. The device comprises p-type and n-type nitride layers, and a plurality of active layers sequentially stacked between the p-type and n-type nitride layers to emit light having different wavelengths. The active layers comprise at least a first active layer to emit a first wavelength light, and a second active layer to emit a second wavelength light, of which wavelength is longer than that of the first wavelength light. Both the first and second active layers are composed of at least one quantum well layer and a quantum barrier layer alternately arranged, and the first active layer is disposed closer to the p-type nitride layer than the second active layer. The number of quantum well layers of the first active layer is less than that of the second active layer.

### RELATED APPLICATION

The present invention is based on, and claims priority from, Korean Application Number 2005-111057, filed on Nov. 19, 2005, the disclosure of which is incorporated by reference herein in its entirety.

### BACKGROUND OF THE INVENTION

1. Field of the Invention

The present invention generally relates to a nitride semiconductor light emitting device (LED), and, more particularly, to a monolithic nitride semiconductor LED, which comprises at least two active layers embodied in the form of a single element to emit light of different wavelengths.

2. Description of the Related Art

Generally, a white LED employing various LEDs is widely used as a backlight unit for illuminating devices or display devices due to excellent luminance and high efficiency.

As approaches for realizing such a white LED, an approach of simply combining separately produced blue, red and green LEDs, and an approach of employing phosphor are well known in the art. The approach of combining the separate multi-color LEDs on a single printed circuit board requires a complicated drive circuit for this purpose, causing a drawback of difficulty in size reduction of the device. Accordingly, a method of manufacturing the white LED using the phosphor is generally used in the art.

As for a conventional method for manufacturing the white LED using the phosphor, a blue LED-based method and an ultraviolet LED-based method are known in the art. For example, in the event of using a blue LED, blue light is converted in wavelength into white light by use of a YAG (Yttrium Aluminum Garnet) phosphor. Namely, a wavelength of blue light emitted from the blue LED excites the YAG phosphor, finally providing white light. However, this method has limits in that powders of the phosphor cause disagreeable effects on the characteristics of the device, and in that excellent impression of color cannot be attained due to reduction in optical efficiency and color compensation index upon excitation of the phosphor.

To solve these problems, there has been an active investigation on a monolithic LED which comprises a plurality of active layers to emit light having different wavelengths without using a phosphor. In this case, it is possible to obtain the monolithic LED by realizing active layers for red, blue and green colors or an active layer of an orange color in a single LED or by realizing the active layers for the blue and green colors in a single LED, followed by combining a red LED therewith. As an example of the monolithic LED which comprises the plurality of active layers, a nitride semiconductor LED comprising two active layers to emit light of different wavelengths is shown in FIG. 1.

Referring to FIG. 1, the nitride semiconductor LED 10 comprises a first conductive nitride layer 12, first and second active layers 14 and 16, and a second conductive layer 17 sequentially stacked on a substrate 11. The first and second conductive nitride layers 12 and 17 are provided with first and second electrodes 19a and 19b.

In the construction shown in FIG. 1, the first and second active layers 14 and 16 are composed of InₓGa₁₋ₓN (0<x≦1) having different compositions to generate, for example, blue light and orange light, respectively, or to generate blue light and green light, respectively.

However, since the nitride semiconductor LED having two or more active layers has a hole injection length much shorter than an electron injection length, there is a problem in that recombination occurs only in a single active layer adjacent to a p-type nitride layer. As such, since light of an inherent color of each active layer is not suitably distributed, there is a limit in realizing a monolithic device for obtaining white light via suitable color distribution.

### SUMMARY OF THE INVENTION

The present invention has been made in view of the above problems, and it is an object of the present invention to provide a nitride semiconductor light emitting device, which comprises a plurality of active layers arranged in consideration of wavelengths of light so as to provide a desirable distribution of inherent light from the plural active layers that emit light of different wavelengths.

In accordance with one aspect of the present invention, the above and other objects can be accomplished by the provision of a nitride semiconductor light emitting device, comprising p-type and n-type nitride layers, and a plurality of active layers sequentially stacked between the p-type and n-type nitride layers to emit light having different wavelengths, wherein the plurality of active layers comprise at least a first active layer to emit a first wavelength light, and a second active layer to emit a second wavelength light, of which wavelength is longer than that of the first wavelength light, both the first and second active layers being composed of at least one quantum well layer and a quantum barrier layer alternately arranged, and wherein the first active layer is disposed closer to the p-type nitride layer than the second active layer, and the number of quantum well layers of the first active layer is less than that of the second active layer.

Preferably, the number of quantum well layers of the second active layer is at least two times that of the first active layer.

According to one embodiment of the present invention, the quantum well layers of the first and second active layers are formed of In₁₋ₓ₁Gaₓ₁N and In₁₋ₓ₂Gaₓ₂N, respectively, and the quantum barrier walls of the first and second active layers are formed of In_{1-y}Ga_{y}N (where x₂<1, 0<x₁<x₂, 0≦y<x₁).

According to the present invention, the first and second active layers may be formed to emit light of specific wavelengths necessary to emit white light. For example, the first active layer is adapted to emit light having a wavelength of about 450˜475 nm, and the second active layer is adapted to emit light having a wavelength of about 550˜600 nm. Alternatively, the first active layer may be adapted to emit light having a wavelength of about 450˜475 nm, and the second active layer may be adapted to emit light having a wavelength of about 510˜535 nm. For this purpose, although a semi-monolithic white light emitting device can be embodied by combining a separate light emitting device emitting red light (600˜635 nm) therewith, it is possible to realize a complete monolithic white light emitting device which further comprises a third active layer to emit light having a wavelength of about 600˜635 nm. In this case, the third active layer is preferably disposed closer to the n-type nitride semiconductor layer than the second active layer.

For the LED where the first active layer emits light having a wavelength of about 450˜475 nm and the second active layer emits light having a wavelength of about 510˜535 nm, the number of quantum well layers of the second active layer is preferably at least five times that of the first active layer. More preferably, the first active layer comprises a single quantum well layer, and the second active layer comprises five or more quantum well layers.

Furthermore, the total thickness of the active layers excluding the first active layer is preferably 200 nm or less, and the number of quantum well layers of the active layers excluding the first active layer is 5 or less in consideration of a hole injection length.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view of a conventional nitride light emitting device;

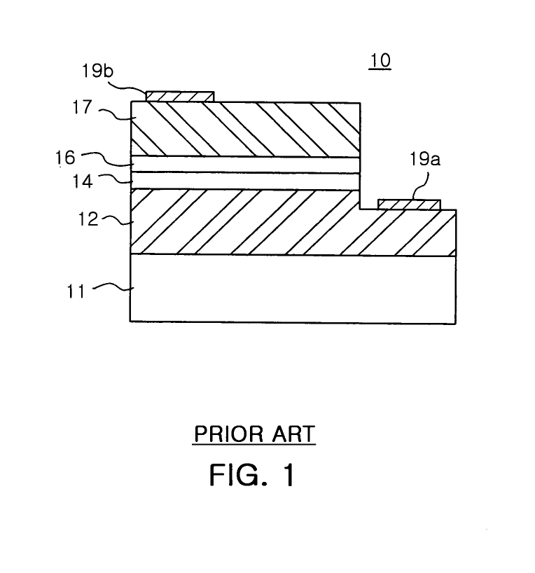

FIGS. 2a to 2c are energy band diagrams of nitride semiconductor light emitting devices according to the present invention, which are different in location of active layers, and in the number of quantum well layers of the active layers; and

FIGS. 3a to 3c are graphs depicting electric luminescence (EL) spectrums of the nitride semiconductor light emitting devices shown in FIGS. 2a to 2c, respectively.

### DETAILED DESCRIPTION OF THE PREFERRED EMBODIMENTS

Preferred embodiments will now be described in detail with reference to the accompanying drawings.

The present invention provides an approach to solve severe non-uniformity in color distribution generated in a conventional monolithic nitride light emitting device comprising two or more active layers by means of arrangement and the number of active layers therein.

The inventors noticed the fact that the severe non-uniformity in color distribution is significantly caused not only by a hole injection length being noticeably shorter than an electron injection length, but also by inherent energy band gaps between the active layers having different wavelengths. Namely, any one of the active layers having different compositions selected to emit light of different wavelengths has tendency to lower recombination efficiency in other active layers due to difference in energy band gap therebetween.

In order to solve this problem, the inventors suggests an approach of providing arrangement of two or more active layers which emit light having different wavelengths, and of providing a suitable number of quantum well layers in each active layer through repetitious experiments.

In order to implement a suitable active layer structure, experiments were carried out in such a way of measuring electric luminescence (EL) of monolithic nitride LEDs which comprise active layers for blue color and green color, and are different in arrangement of the active layers and in the number of quantum well layers.

### EXAMPLES

After manufacturing A, B and C-type nitride semiconductor light emitting devices which comprise two active layers to emit light having different wavelength as described below, luminescence properties of each LED were measured.

A. Blue Color Active Layer (x3) and Green Color Active Layer (x3)

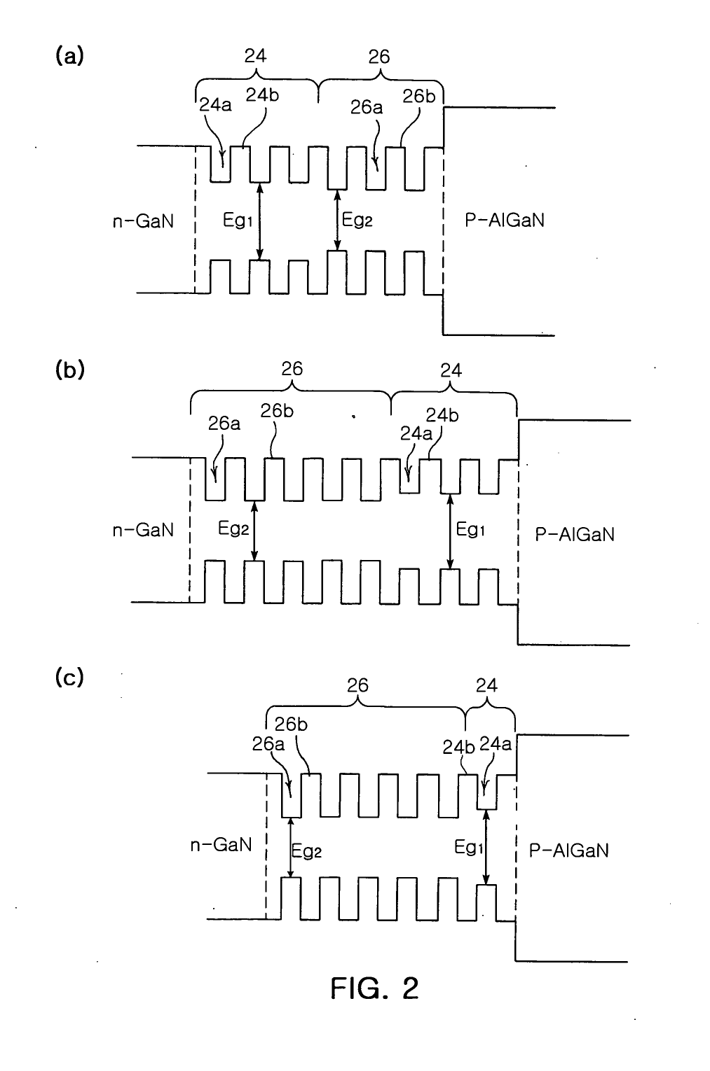

First, an n-type GaN layer having a thickness of 1.2 μm was formed on a sapphire substrate. Then, active layers of a multi-quantum well structure were formed on the n-type GaN layer, in which the active layers comprise a blue color active layer 24 composed of three pairs of In_{0.1}Ga_{0.9}N quantum well layers 24a and GaN quantum barrier layers 24b, and a green color active layer 26 composed of three pairs of In_{0.15}Ga_{0.85}N quantum well layers 26a and GaN quantum barrier layers 26b (see FIG. 2a).

A p-type AlGaN layer having a thickness of about 0.5 μm and a p-type GaN layer having a thickness of about 1.5 μm were sequentially formed on the green active layer 26. Then, p-side and n-side electrodes are formed by mesa-etching the layers to partially expose the n-type GaN layer.

B. Green Color Active Layer (x5) and Blue Color Active Layer (x3)

A nitride LED was fabricated under a similar condition as in the above example except for configuration of active layers of the multi-quantum well structure. In this example, the active layers comprise a green color active layer 26 composed of five pairs of In_{0.15}Ga_{0.85}N quantum well layers 26a and GaN quantum barrier layers 26b, and a blue color active layer 24 composed of three pairs of In_{0.1}Ga_{0.9}N quantum well layers 24a and GaN quantum barrier layers 24b on an n-type GaN layer as shown in FIG. 2b.

C. Green Color Active Layer (x5) and Blue Color Active Layer (x1)

A nitride LED was fabricated substantially with the same condition as that of the above examples except for configuration of active layers of the multi-quantum well structure. In this example, the active layers comprise a green color active layer 26 composed of five pairs of In_{0.15}Ga_{0.85}N quantum well layers 26a and GaN quantum barrier layers 26b, and a blue color active layer 24 composed of a pair of In_{0.1}Ga_{0.9}N quantum well layers 24a and GaN quantum barrier layers 24b on an n-type GaN layer as shown in FIG. 2c.

It can be understood that the active layers of the respective nitride LEDS constructed as above have energy band diagrams as shown in FIGS. 2a to 2c, respectively.

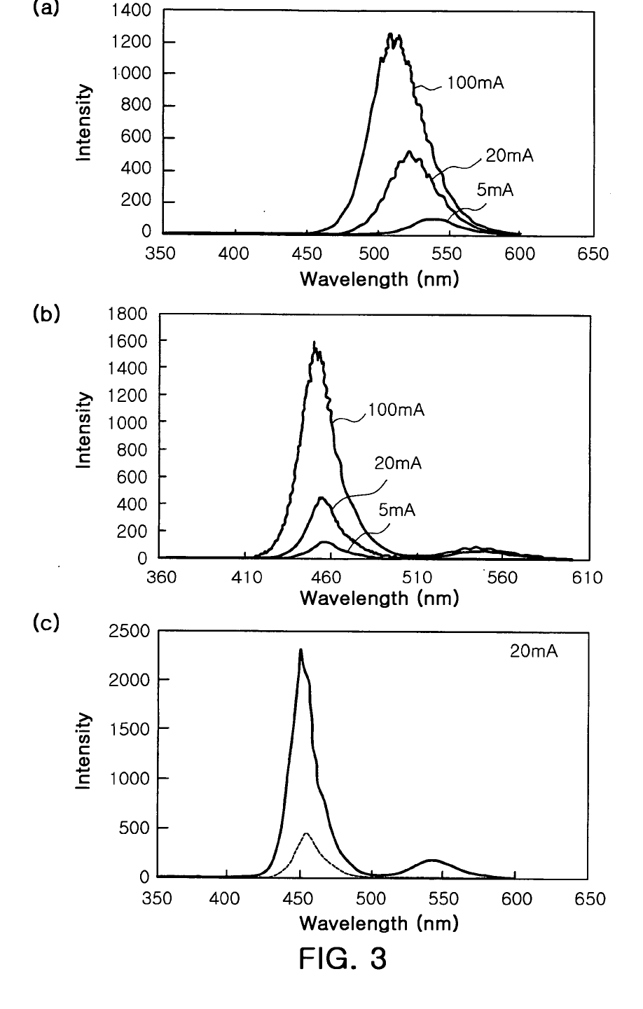

Then, electric luminescence of the respective nitride LEDs of A, B and C types were measured at different drive currents of 5 mA, 20 mA and 100 mA. Results of the measurements are shown in FIGS. 3a to 3c.

Referring to FIG. 3a, the A-type nitride LED emits only green light having a wavelength of about 510˜535 nm, and emits very little blue light. On the other hand, referring to FIGS. 3b and 3c (see a solid line in FIG. 3c), although blue light having a wavelength of about 450˜475 nm is predominant for the B and C-type nitride LEDs, green light having a wavelength of about 510˜535 nm is also slightly emitted.

This can be understood as a result of influence of a sequence of stacking the active layers for long wavelength and the active layers for short wavelength. More specifically, this phenomenon is attributable to an increase in amount of holes injected into an active layer adjacent to the n-type nitride layer due to a noticeably lower mobility of holes than that of electrons when the active layer adjacent to the p-type nitride layer has a relatively large band gap.

For example, for the A-type nitride LED, since the quantum well layer 26a for green light having a lower band gap Eg2 than that of the quantum well layer 24a for blue light is disposed closer to the p-type nitride layer than the quantum well layer 24a, recombination of holes and electrons occur only in the active layer for the green light due to a higher barrier with respect to the holes injected from the p-type nitride layer than in the B or C-type nitride LED.

With the results of the experiment, it can be found that it is more desirable to dispose the short wavelength active layer closer to the p-type nitride layer than the long wavelength active layer.

Moreover, from the results of the experiment, it can be confirmed that it is necessary to suitably determine the number of the quantum well layers in each active layer according to the wavelength of light through comparison between the B type and the C type, in addition to the stacking sequence of the active layers based on the wavelengths of light.

As apparent from FIG. 3c, at the same condition of 20 mA, the C type nitride LED (indicated by the solid line) is improved in luminescence efficiency of green light, compared with that of the B type nitride LED. It can be understood that this result is caused by different numbers of quantum well layers in each active layer.

Namely, the C type nitride LED comprises the quantum well layers 24a for blue color less than those of the B type nitride LED, so that confinement of holes by the quantum well layers 24a for blue color luminescence is increased, thereby enhancing recombination efficiency.

As such, it is possible to improve hole injection efficiency into the long wavelength active layer adjacent to the n-type nitride layer by decreasing the number of quantum well layers in the short wavelength active layer adjacent to the p-type nitride layer so as to attain reduction in the total thickness of the active layers thereby.

With the results of this experiment, it is necessary for a desirable condition under consideration of the hole injection length to have the number of quantum well layers of the active layer for green color at least five times that of the active layer for blue color. However, since it is important to decrease the number of active layers for blue color adjacent to the p-type nitride layer, it is more preferable that the number of quantum well layers of the active layer for blue color is one, and the number of quantum well layers of the active layer for green color is five or more.

In particular, since it is necessary to consider the general hole injection length, it is preferable that the thickness of the active color for blue color adjacent to the p-type nitride layer is 200 nm or less.

Unlike the above examples, it is possible to consider an LED which comprises three active layers emitting light having different wavelengths. Even in this case, it is preferable that the total thickness of active layers excluding at least a long wavelength active layer adjacent to the n-type nitride layer is 200 nm or less, and that the number of quantum well layers of the active layers excluding the long wavelength active layer is 5 or less.

In the nitride LED according to the present invention, the luminescence wavelength of the active layer can generally be determined by a content of indium contained in the quantum well layer. In this case, quantum well layers of the short wavelength and long wavelength active layers are formed of In₁₋ₓ₁Gaₓ₁N and In₁₋ₓ₂Gaₓ₂N, respectively, and quantum barrier walls thereof are formed of In_{1-y}Ga_{y}N (where x₂<1, 0<x₁<x₂, 0≦y<x₁).

More specifically, the short wavelength and long wavelength active layers may be embodied to emit light having suitable wavelengths necessary for white color luminescence. For example, the short wavelength active layer is adapted to emit light having a wavelength of about 450˜475 nm, and the long wavelength active layer is adapted to emit light having a wavelength of about 550˜600 nm.

Alternatively, the short wavelength active layer may be adapted to emit light having a wavelength of about 450˜475 nm, and the long wavelength active layer may be adapted to emit light having a wavelength of about 510˜530 nm. For this purpose, although a semi-monolithic white LED can be embodied by combining a separate LED emitting red light (600˜635 nm) therewith, it is possible to realize a complete monolithic white LED which further comprises an active layer for red color to emit light having a wavelength of about 600˜635 nm. In this case, the active layer for red color is preferably disposed closer to the n-type nitride semiconductor layer than other active layers, since the active layer for red color exhibits the greatest difference in energy band gap with respect to the p-type nitride layer.

As apparent from the above description, according to the present invention, a short wavelength active layer among a plurality of active layers is disposed adjacent to a p-type nitride layer while reducing the number of quantum well layers of the short wavelength active layer to be less than the number of long wavelength active layers, thereby allowing inherent luminescence of the plural active layers emitting light of different wavelengths to be distributed at a desired level. Such a technique can be usefully adapted in manufacture of a monolithic white light emitting device.

It should be understood that the embodiments and the accompanying drawings have been described for illustrative purposes and the present invention is limited only by the following claims. Further, those skilled in the art will appreciate that various modifications, additions, and substitutions are allowed without departing from the scope and spirit of the invention as set forth in the accompanying claims.

What is claimed is:

1. A nitride semiconductor light emitting device (LED), comprising p-type and n-type nitride layers, and a plurality of active layers sequentially stacked between the p-type and n-type nitride layers to emit light having different wavelengths,
wherein the plurality of active layers comprise at least a first active layer to emit a first wavelength light, and a second active layer to emit a second wavelength light, of which wavelength is longer than that of the first wavelength light, both the first and second active layers being composed of at least one quantum well layer and a quantum barrier layer alternately arranged, and
wherein the first active layer is disposed closer to the p-type nitride layer than the second active layer, and the number of quantum well layers of the first active layer is less than that of the second active layer.

2. The nitride semiconductor LED according to claim 1, wherein the number of quantum well layers of the second active layer is at least two times that of the first active layer.

3. The nitride semiconductor LED according to claim 1, wherein the quantum well layers of the first and second active layers are formed of In₁₋ₓ₁Gaₓ₁N and In₁₋ₓ₂Gaₓ₂N, respectively, and the quantum barrier walls of the first and second active layers are formed of In_{1-y}Ga_{y}N (where x₂<1, 0<x₁<x₂, 0≦y<x₁).

4. The nitride semiconductor LED according to claim 3, wherein the first active layer emits light having a wavelength of about 450˜475 nm, and the second active layer emits light having a wavelength of about 550˜600 nm.

5. The nitride semiconductor LED according to claim 3, wherein the first active layer emits light having a wavelength of about 450˜475 nm, and the second active layer emits light having a wavelength of about 510˜535 nm.

6. The nitride semiconductor LED according to claim 5, wherein the plurality of active layers further comprises a third active layer composed of at least one quantum well layer and a quantum well barrier alternately arranged to emit light having a wavelength of about 600˜635 nm, the third active layer being disposed closer to the n-type nitride semiconductor layer than the second active layer.

7. The nitride semiconductor LED according to claim 5, wherein the number of quantum well layers of the second active layer is at least five times that of the first active layer.

8. The nitride semiconductor LED according to claim 5, wherein the first active layer comprises a single quantum well layer, and the second active layer comprises five or more quantum well layers.

9. The nitride semiconductor LED according to claim 1, wherein the total thickness of the active layers excluding the first active layer is 200 nm or less.

10. The nitride semiconductor LED according to claim 1, wherein the number of quantum well layers of the active layers excluding the first active layer is five or less.
